(19) United States
(12) Patent Application Publication
(10) Pub. No.: US 2024/0404921 A1
(43) Pub. Date: Dec. 5, 2024

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: Choongbin Yim, Suwon-si (KR); Chengtar Wu, Suwon-si (KR)

(21) Appl. No.: 18/439,461

(22) Filed: Feb. 12, 2024

(30) Foreign Application Priority Data
Jun. 1, 2023 (KR) 10-2023-0071047

(51) Int. Cl. H01L 23/482; H01L 23/00; H01L 23/498; H01L 25/065

(52) U.S. Cl. CPC H01L 23/4821; H01L 23/49816; H01L 23/49822; H01L 24/08; H01L 24/16; H01L 25/0652; H01L 2224/08146; H01L 2224/08155; H01L 2224/16146; H01L 2224/16157; H01L 2924/01029; H01L 2924/01047; H01L 2924/0105; H01L 2924/1431; H01L 2924/1434; H01L 2924/15311

(57) ABSTRACT

A semiconductor package includes: a redistribution layer structure; first semiconductor and second dies on the redistribution, the second semiconductor die positioned next to the first semiconductor die; core balls positioned on the redistribution structure and next to the first semiconductor chip die; a bridge die configured to electrically connect the first and second semiconductor dies to each other on the first and second semiconductor dies; a substrate including an upper plate portion and a sidewall portion, the upper plate portion and the sidewall portion defining a cavity, the upper plate portion positioned on the bridge die, the side wall portion positioned on the core balls, the bridge die positioned within the cavity; and a molding material configured to mold the first semiconductor die, the second semiconductor die, the core balls, and the bridge die between the redistribution layer structure and the substrate.

### CROSS-REFERENCE TO RELATED APPLICATION

This application claims priority to and the benefit of Korean Patent Application No. 10-2023-0071047, filed in the Korean Intellectual Property Office on Jun. 1, 2023, the entire contents of which are incorporated herein by reference.

### TECHNICAL FIELD

The present disclosure relates to a semiconductor package and a manufacturing method therefor.

### BACKGROUND

The semiconductor industry seeks to increase integration density so that more passive or active devices can be integrated within a given area. To develop technology for miniaturizing a circuit line width of a semiconductor front-end process gradually faced limitations, the semiconductor industry has supplemented limitations of semiconductor front-end processes by developing semiconductor package techniques capable of having high integration densities. Semiconductor chips tend to arranged side by side, and packaging techniques for semiconductors include vertically stacking packaged semiconductor packages.

Generally, an upper structure and a lower structure are electrically connected by metal posts in the semiconductor package by arranging them side by side and stacking the packaged semiconductor packages vertically. However, the metal posts have a long electrical path between the upper structure and the lower structure, and such a long electrical path makes it difficult to implement a high-performance semiconductor package. For example, forming a long metal post can include repeatedly exposing, developing, etching, and depositing, and accordingly, a turnaround time (TAT) may increase. Thus, a risk of yield degradation may occur in the process of forming the metal post.

In addition, in conventional semiconductor packaging technology, a substrate having a silicon bridge inserted therein is positioned under semiconductor dies arranged side by side to electrically connect the semiconductor dies arranged side by side. However, as the pitch of the I/Os of the semiconductor have decreased to keep up with demands, it has become difficult to match the fine pitch I/Os of the semiconductor dies with a normal pitch I/Os of a substrate in which silicon bridges are inserted.

Accordingly, it is necessary to develop a new semiconductor package technology that can solve the problems of the conventional semiconductor package technology.

### SUMMARY

The present disclosure attempts to provide a semiconductor package in which a bridge die is positioned on a first semiconductor die and a second semiconductor die and within a cavity of a substrate, and a redistribution layer structure is positioned on lower surfaces of the first semiconductor die and the second semiconductor die, for electrical connection in a horizontal direction between the first semiconductor die and the second semiconductor die positioned side by side.

The present disclosure attempts to provide a semiconductor package including a substrate having a cavity structure and core balls by replacing conductive posts, for electrical connection in a vertical direction between an upper structure and a lower structure of a package on package (PoP).

In general, aspects of the subject matter described in this specification can be embodied in a semiconductor package including: a redistribution layer structure; a first semiconductor die on the redistribution layer structure; a second semiconductor die positioned on the redistribution layer structure and side by side with the first semiconductor die; a plurality of core balls positioned on the redistribution structure and side by side with the first semiconductor chip die; a bridge die configured to electrically connect the first semiconductor die and the second semiconductor die to each other on the first semiconductor die and the second semiconductor die; a substrate configured to include an upper plate portion and a sidewall portion, wherein the substrate includes a cavity defined by the upper plate portion and the sidewall portion, the upper plate portion is positioned on the bridge die, the side wall portion is positioned on the core balls, the bridge die is positioned within the cavity; and a molding material configured to mold the first semiconductor die, the second semiconductor die, the core balls, and the bridge die between the redistribution layer structure and the substrate.

Another general aspect can be embodied in a semiconductor package including: a redistribution layer structure; a first semiconductor die on the redistribution layer structure; a second semiconductor die positioned on the redistribution layer structure and side by side with the first semiconductor die; a plurality of core balls positioned on the redistribution structure and side by side with the first semiconductor chip die; an interconnection structure on the first semiconductor die and the second semiconductor die; a bridge die on the interconnection structure, wherein the interconnection structure electrically connects the bridge die and the first semiconductor die, and the bridge die and the second semiconductor die, and the bridge die electrically connects the first semiconductor die and the second semiconductor die; a substrate configured to include an upper plate portion and a sidewall portion, wherein the substrate includes a cavity defined by the upper plate portion and the sidewall portion, the upper plate portion is positioned on the bridge die, the side wall portion is positioned on the core balls, the bridge die is positioned within the cavity; a molding material configured to mold the first semiconductor die, the second semiconductor die, the core balls, and the bridge die between the redistribution layer structure and the substrate; and a third semiconductor die on the substrate.

Another general aspect can be embodied in a manufacturing method for a semiconductor package, including: forming a redistribution layer structure on a carrier; mounting a first semiconductor die and a second semiconductor die side by side on the redistribution layer structure; bonding a bridge die on the first semiconductor die and the second semiconductor die; bonding a plurality of core balls on the redistribution layer structure; bonding a substrate on the core balls, wherein the substrate includes an upper plate portion and a side wall portion, the substrate includes a cavity defined by the upper plate portion and the sidewall portion, the upper plate portion is positioned on the bridge die, the sidewall portion is positioned on the core balls, and the bridge die is positioned within the cavity; and molding the first semiconductor die, the second semiconductor die, the core balls, and the bridge die with a molding material between the redistribution layer structure and the substrate.

In a semiconductor package including a first semiconductor die and a second semiconductor die disposed side by side, a bridge die may be positioned on the first semiconductor die and the second semiconductor die, and a redistribution layer structure may be positioned on lower surfaces of the first semiconductor die and the second semiconductor die. As a result, it is possible to match the fine pitch I/Os of the redistribution layer structure to the fine pitch I/Os of the semiconductor dies, and to reduce an electrical path in the horizontal direction.

The bridge die is positioned on the first semiconductor die and the second semiconductor die and within the cavity of the substrate and a substrate with a cavity structure and core balls may be used by replacing the conductive posts. Accordingly, it is possible to simplify the manufacturing process, to improve yield, to reduce the electrical path in the vertical direction, and to reduce the thickness of the semiconductor package.

The rigidity of a package-on-package (PoP) structure may be improved by positioning the bridge die in the cavity of the substrate and structurally and electrically connecting the upper structure and the lower structure with the substrate.

### BRIEF DESCRIPTION OF THE DRAWINGS

FIG. 1 illustrates a cross-sectional view showing an example of a semiconductor package.

FIG. 2 illustrates a cross-sectional view showing an example of a semiconductor package.

FIG. 3 illustrates a cross-sectional view showing an example of a core ball.

FIG. 4 illustrates a cross-sectional view showing an example of a core ball.

FIG. 5 illustrates a cross-sectional view showing an example of a core ball.

FIG. 6 to FIG. 15 illustrate cross-sectional views for describing an example of a method for manufacturing a semiconductor package.

### DETAILED DESCRIPTION

The present disclosure will be described more fully hereinafter with reference to the accompanying drawings, in which examples of the present disclosure are shown. As those skilled in the art would realize, the described examples may be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Hereinafter, a semiconductor package 100 and a manufacturing method for the semiconductor package 100 according to an embodiment will be described with reference to drawings.

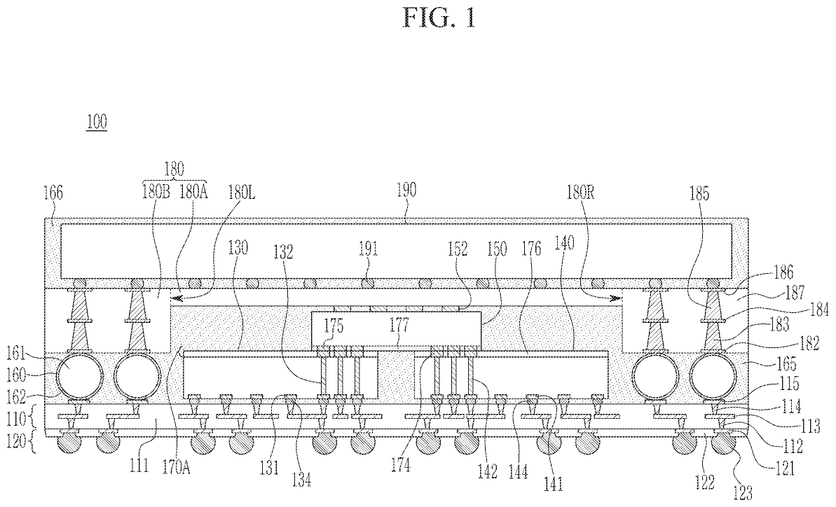

FIG. 1 illustrates a cross-sectional view showing a semiconductor package 100.

In the cross-sectional view of the semiconductor package 100 illustrated in FIG. 1, a bridge die 150 is positioned on a first semiconductor die 130 and a second semiconductor die 140 for electrical connection in a horizontal direction between the first semiconductor die 130 and the second semiconductor die 140, core balls 160 and a substrate 180 on the core balls 160 are positioned for electrical connection in a vertical direction between the first semiconductor die 130 and a third semiconductor die 190 and between the second semiconductor die 140 and the third semiconductor die 190, and the first semiconductor die 130 and the bridge die 150, and the second semiconductor die 140 and the bridge die 150 are electrically connected by hybrid bonding.

Referring to FIG. 1, the semiconductor package 100 may include a redistribution layer structure 110, an external connection structure 120, the first semiconductor die 130, the second semiconductor die 140, the bridge die 150, the core balls 160, a first molding material 165, an interconnection structure 170A, the substrate 180, the third semiconductor die 190, and a second molding material 166. In some implementations, the semiconductor package 100 may include a package on package (PoP). In some implementations, the semiconductor package 100 may include a fan out wafer level package (FOWLP) or a fan out panel level package (FOPLP).

The redistribution layer structure 110 may include a dielectric layer 111, first redistribution layer vias 112, first redistribution layer lines 113, and second redistribution layer vias 114 in the dielectric layer 111, and connection pads 115 on the dielectric layer 111. In some implementations, redistribution layer structures that include fewer or greater numbers of redistribution layer lines, redistribution layer vias, and connection pads are within the scope of the present disclosure. The first semiconductor die 130, the second semiconductor die 140, and the core balls 160 may be positioned on an upper surface of the redistribution layer structure 110. The external connection structure 120 may be positioned on a lower surface of the redistribution layer structure 110.

The dielectric layer 111 protects and insulates the first redistribution layer vias 112, the first redistribution layer lines 113, and the second redistribution layer vias 114. The connection pads 115 may be positioned on an upper surface of the dielectric layer 111.

The first redistribution layer via 112 may be positioned between the first redistribution layer line 113 and the conductive pad 121 of the external connection structure 120. The first redistribution layer via 112 may electrically connect the first redistribution layer line 113 to the conductive pad 121 in the vertical direction. The first redistribution layer line 113 may be positioned between the first redistribution layer via 112 and the second redistribution layer via 114. The first redistribution layer line 113 may electrically connect the first redistribution layer via 112 and the second redistribution layer via 114 in a horizontal direction. The second redistribution layer via 114 may be positioned between the first redistribution layer line 113 and first connection members 134 of the first semiconductor die 130, between the first redistribution layer line 113 and second connection members 144 of the second semiconductor die 140, and between the first redistribution layer line 113 and the connection pad 115. The second redistribution layer via 114 may electrically connect the first connection members 134 of the first semiconductor die 130 to the first redistribution layer line 113, the second connection members 144 of the second semiconductor die 140 to the first redistribution layer line 113, and the connection pad 115 to the first redistribution layer line 113 in the vertical direction. The connection pad 115 may be positioned between the core ball 160 and the second redistribution layer via 114. The connection pad 115 may electrically connect the core ball 160 to the second redistribution layer via 114 in the vertical direction.

In the conventional semiconductor packaging technology, a substrate having a bridge die inserted therein is positioned under semiconductor dies arranged side by side to electrically connect the semiconductor dies arranged side by side. However, with the development of semiconductor package technology, the spacing I/O of semiconductor dies have gradually become finer, and it has become difficult to match fine pitch I/Os of semiconductor dies to normal pitch I/Os of a substrate.

In order to solve this problem, the bridge die 150 may be positioned on upper surfaces of the first semiconductor die 130 and the second semiconductor die 140 to electrically connect the first semiconductor die 130 and the second semiconductor die 140 in the horizontal direction, and the fine pitch I/Os of the semiconductor dies may be matched with the fine pitch I/Os of the redistribution layer structure 110 by positioning the redistribution layer structure 110 capable of forming fine patterns on the lower surfaces of the first semiconductor die 130 and the second semiconductor die 140.

The external connection structure 120 may be positioned on a lower surface of the redistribution layer structure 110. The external connection structure 120 may include conductive pads 121, an insulating layer 122, and external connection members 123. The conductive pad 121 may electrically connect the first redistribution layer via 112 of the redistribution layer structure 110 to the external connection member 123. The insulation layer 122 may include a plurality of openings for soldering. The insulating layer 122 prevents the external connection member 123 from being short-circuited. The external connection member 123 may electrically connect the semiconductor package 100 to an external device.

The first semiconductor die 130 may include first semiconductor chips, first lower connection pads 131, first through silicon vias (TSVs) 132, and first connection members 134. In some implementations, the first semiconductor die 130 may include an application processor (AP). In some implementations, the first semiconductor chip may include at least one of a central processing unit (CPU), a graphic processing unit (GPU), a memory, a controller, a codec, a sensor, or a communication chip.

The first lower connection pad 131 may be positioned between the first connection member 134 and the first through silicon via (TSV) 132. The first lower connection pad 131 may electrically connect the first through silicon via (TSV) 132 to the first connection member 134. The first lower connection pad 131 may include at least one of copper, aluminum, silver, tin, gold, nickel, lead, titanium, or an alloy thereof.

The first through silicon via (TSV) 132 may be positioned between the first lower connection pad 131 and the first bonding pad 174. The first through silicon via (TSV) 132 may electrically connect the first bonding pad 174 to the first lower connection pad 131. In some implementations, the first through silicon via (TSV) 132 may include at least one of tungsten, aluminum, copper, or an alloy thereof.

The second semiconductor die 140 may include second semiconductor chips, second lower connection pads 141, second through silicon vias (TSVs) 142, and second connection members 144. In some implementations, the second semiconductor die 140 may include an application processor (AP). In some implementations, the second semiconductor chip may include at least one of a central processing unit (CPU), a graphic processing unit (GPU), a memory, a controller, a codec, a sensor, or a communication chip.

The second lower connection pad 141 may be positioned between the second connection member 144 and the second through silicon via (TSV) 142. The second lower connection pad 141 may electrically connect the second through silicon via (TSV) 142 to the second connection member 144. The second lower connection pad 141 may include at least one of copper, aluminum, silver, tin, gold, nickel, lead, titanium, or an alloy thereof.

The second through silicon via (TSV) 142 may be positioned between the second lower connection pad 141 and the first bonding pad 174. The second through silicon via (TSV) 142 may electrically connect the first bonding pad 174 to the second lower connection pad 141. In some implementations, the second through silicon via (TSV) 142 may include at least one of tungsten, aluminum, copper, or an alloy thereof.

In the semiconductor package 100 according to the present disclosure, the bridge die 150 is spaced apart from the redistribution layer structure 110 that transfers signals and power. Accordingly, the first through silicon via (TSV) 132 may be positioned in the first semiconductor die 130, the second through silicon via (TSV) 142 may be positioned in the second semiconductor die 140, and a speed of receiving signals and power of the bridge die 150 and responding thereto may be increased by connecting the first through silicon via (TSV) 132 and the second through silicon via (TSV) 142 to the bridge die 150.

The bridge die 150 may be positioned on the first semiconductor die 130 and the second semiconductor die 140. In some implementations, the bridge die 150 may be positioned on a portion of an upper surface of the first semiconductor die 130 and on a portion of an upper surface of the second semiconductor die 140. The bridge die 150 may electrically connect the first semiconductor die 130 and the second semiconductor die 140. Accordingly, the first semiconductor die 130 and the second semiconductor die 140 may exchange signals with each other through the bridge die 150. The bridge die 150 may be connected to the first semiconductor die 130 and the second semiconductor die 140 by the interconnection structure 170A. In some implementations, the bridge die 150 may include a silicon bridge layer. In some implementations, the bridge die 150 may include a memory semiconductor chip or a high bandwidth memory (HBM).

The first semiconductor die 130 and the second semiconductor die 140 of the semiconductor package 100 may be bonded to the bridge die 150 by the interconnection structure 170A. The interconnection structure 170A may include first bonding pads 174 and a first insulating layer 176 on upper surfaces of the first semiconductor die 130 and the second semiconductor die 140, and second bonding pads 175 and a second insulating layer 177 on a lower surface of the bridge die 150. The first bonding pads 174 is directly bonded to the second bonding pads 175 by metal-metal hybrid bonding, and the first insulating layer 176 is directly bonded to the second insulating layer 177 by non-metal-non-metal hybrid bonding. The hybrid bonding is to bond two devices by fusing same materials of the two devices using a bonding property of a same material. Herein, hybrid indicates that two different types of bonding are made, e.g., bonding two devices with a first type of metal-metal bonding and a second type of non-metal-non-metal bonding. The hybrid bonding may make it possible to form I/Os with a fine pitch.

The core balls 160 may be positioned between the redistribution layer structure 110 and the substrate 180 and may electrically connect the substrate 180 to the redistribution layer structure 110. In conventional package-on-package (PoP) technology, an upper structure and a lower structure are electrically connected by means of metal posts. However, the metal posts have a long electrical path between the upper structure and the lower structure, and such a long electrical path makes it difficult to implement a high-performance semiconductor package. In order to form a long metal post, a same process such as exposure, development, etching, and deposition must be repeatedly performed, and accordingly, a turnaround time (TAT) may increase. Thus, a risk of yield degradation may occur in the process of forming the metal post. Accordingly, according to the present disclosure, by using pre-manufactured core balls 160 instead of the metal posts, it is possible to simplify a process and improve yield.

The first molding material 165 may mold the first semiconductor die 130, the second semiconductor die 140, the bridge die 150, and the core balls 160 between the redistribution layer structure 110 and the substrate 180.

The substrate 180 may be positioned on the core balls 160 and on an upper surface of the bridge die 150. The substrate 180 may be positioned on a lower surface of the third semiconductor die 190. The substrate 180 may electrically connect the third semiconductor die 190 to the core balls 160. The substrate 180 may include a printed circuit board (PCB). The substrate 180 may include an embedded trace substrate (ETS).

According to the present disclosure, in the package on package (PoP), instead of using a back side redistribution layer structure to connect the upper structure and the lower structure, the upper structure and the lower structure may be connected using the substrate 180. As a result, the semiconductor package 100 with improved rigidity and resistance to warpage may be provided. In addition, since the semiconductor package 100 is manufactured using the substrate 180 manufactured in advance, a manufacturing process for the semiconductor package 100 is simplified, and the turn around time (TAT) consumed in manufacturing the semiconductor package 100 may be reduced. In addition, since the semiconductor package 100 is manufactured using the previously separately tested substrate 180, product yield of the semiconductor package 100 may be improved. In addition, since a process of manufacturing a back side redistribution layer structure in which a plurality of fine patterns is formed may be omitted, a number of steps in the redistribution layer process may be reduced and a manufacturing cost may be reduced.

The substrate 180 may include an upper plate portion 180A and a sidewall portion 180B. The substrate 180 may include a cavity defined by the upper plate portion 180A and the sidewall portion 180B. The upper plate portion 180A may be defined as a substrate between dotted lines 180L and 180R. The sidewall portion 180B may be defined as a substrate outside the dotted line 180L and outside the dotted line 180R. The upper plate portion 180A may be positioned on the bridge die 150. A solder resist patch 152 may be attached between the upper plate portion 180A and the bridge die 150 in order to eliminate a gap between a lower surface of the upper plate portion 180A and an upper surface of the bridge die 150 and to bond the upper plate portion 180A and the bridge die 150. The sidewall portion 180B may be positioned on the core balls 160. The bridge die 150 may be positioned into the cavity.

Although not illustrated, the upper plate portion 180A may include a wiring layer and a via. The sidewall portion 180B may include a first wiring layer 182, a first via 183, a second wiring layer 184, a second via 185, a third wiring layer 186, and an insulating layer 187.

The first wiring layer 182 is disposed between the core ball 160 and the first via 183. The first wiring layer 182 may electrically connect the first via 183 to the core ball 160. The first wiring layer 182 may be directly bonded to the core ball 160. The first via 183 is positioned between the first wiring layer 182 and the second wiring layer 184. The first via 183 may electrically connect the second wiring layer 184 to the first wiring layer 182. The second wiring layer 184 is disposed between the first via 183 and the second via 185. The second wiring layer 184 may electrically connect the second via 185 to the first via 183. The second via 185 is positioned between the second wiring layer 184 and the third wiring layer 186. The second via 185 may electrically connect the third wiring layer 186 to the second wiring layer 184. The third wiring layer 186 is disposed between the second via 185 and the third connection member 191 of the third semiconductor die 190. The third wiring layer 186 may electrically connect the third connection member 191 of the third semiconductor die 190 to the second via 185. The insulating layer 187 may surround the first wiring layer 182, the first via 183, the second wiring layer 184, the second via 185, and the third wiring layer 186. In some implementations, a substrate 180 includes fewer or greater numbers of wiring layers and vias.

In some implementations, the first via 183 and the second via 185 may have a truncated cone shape in which a diameter becomes narrower from a lower surface to an upper surface. In some implementations, the first via 183 and the second via 185 may have a truncated cone shape in which a diameter becomes narrower from an upper surface to a lower surface. In some implementations, the first via 183 and the second via 185 may include a cylindrical shape having a constant diameter from an upper surface to a lower surface.

The third semiconductor die 190 may be positioned on the substrate 180. The third semiconductor die 190 may include a single chip such as a DRAM or multiple chips such as a high bandwidth memory (HBM). The third semiconductor die 190 may include third connection members 191. The third connection member 191 may electrically connect the third semiconductor die 190 to the substrate 180. In some implementations, the third connection member 191 may include a micro bump or a solder ball.

The second molding material 166 may mold the third semiconductor die 190 on the substrate 180.

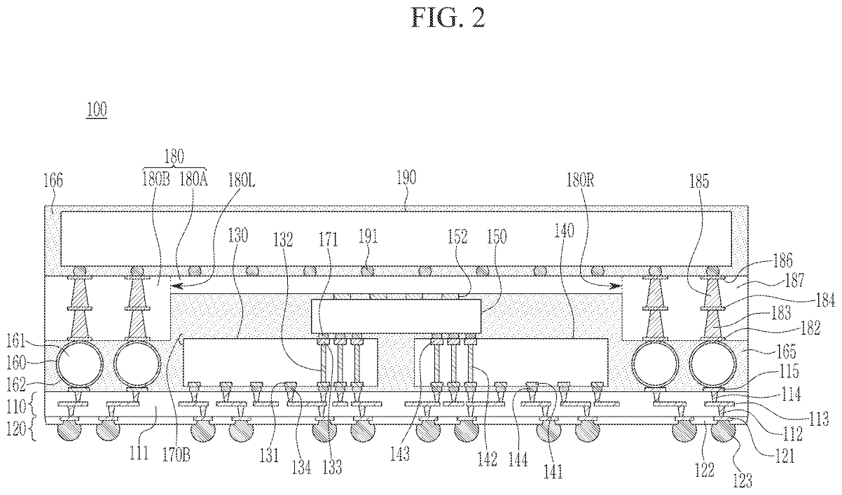

FIG. 2 illustrates a cross-sectional view showing a semiconductor package 100.

In FIG. 2, a cross-sectional view of the semiconductor package 100 is illustrated, in which the first semiconductor die 130 and the bridge die 150, and the second semiconductor die 140 and the bridge die 150 are electrically connected by flip chip bonding.

Referring to FIG. 2, the semiconductor package 100 may include a redistribution layer structure 110, an external connection structure 120, the first semiconductor die 130, the second semiconductor die 140, the bridge die 150, the core balls 160, the first molding material 165, an interconnection structure 170B, the substrate 180, the third semiconductor die 190, and a second molding material 166. Among them, the contents described with respect to the semiconductor package 100 of FIG. 1 may be equally applied to other components except the interconnection structure 170B the first semiconductor die 130 further including first upper connection pads 133, the second semiconductor die 140 further including second upper connection pads 143, and the interconnection structure 170B.

The first semiconductor die 130 may include first upper connection pads 133 between the first through silicon vias (TSVs) 132 and the fourth connection members 171. The first upper connection pads 133 may electrically connect the fourth connection member 171 to the first through silicon vias (TSVs) 132. The first upper connection pad 133 may include at least one of copper, aluminum, silver, tin, gold, nickel, lead, titanium, or an alloy thereof.

The second semiconductor die 140 may include second upper connection pads 143 between the second through silicon vias (TSVs) 142 and the fourth connection members 171. The second upper connection pads 143 may electrically connect the fourth connection member 171 to the second through silicon vias (TSVs) 142. The second upper connection pad 143 may include at least one of copper, aluminum, silver, tin, gold, nickel, lead, titanium, or an alloy thereof.

The interconnect structure 170B may be positioned between the first semiconductor die 130 and the bridge die 150 and between the second semiconductor die 140 and the bridge die 150. The interconnection structure 170B may include fourth connection members 171. The fourth connection member 171 may electrically connect the bridge die 150 to the first upper connection pad 133 and the bridge die 150 to the second upper connection pad 143. In some implementations, the fourth connection member 171 may include a micro bump.

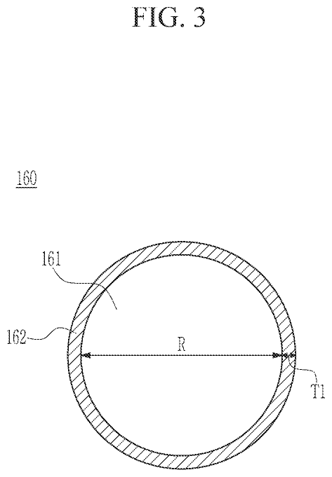

FIG. 3 illustrates a cross-sectional view showing the core ball 160.

Referring to FIG. 3, the core ball 160 may include an inner core 161 and a first outer conductive layer 162 covering the inner core 161. In addition, although not illustrated, the core ball 160 may include at least one of a nickel layer or a copper layer between the inner core 161 and the first outer conductive layer 162.

The core ball 160 serves as a support structure between the lower redistribution layer structure 110 and the substrate 180 by means of the inner core 161. The inner core 161 relieves stress applied to the core ball 160 from the redistribution layer structure 110 and the substrate 180 and allows the core balls 160 to have a uniform height so that a spacing between the redistribution layer structure 110 and the substrate 180 can be maintained constantly.

In some implementations, the inner core 161 may include a plastic material, a polymer material, or a metal. In some implementations, the plastic material may include a thermosetting resin, a thermoplastic resin, or an elastomer. In some implementations, the thermosetting resin may include an epoxy-based resin, a melamine-formaldehyde-based resin, a benzoguanamine-formaldehyde-based resin, divinylbenzene, divinyl ether, oligo or polydiacrylate, or an alkylenebisacrylamide resin. In some implementations, the thermoplastic resin may include polyvinyl chloride, polyethylene, polystyrene, nylon or a polyacetal resin. In some implementations, the polymer material may include natural rubber or synthetic rubber. In some implementations, the metal may include a copper or copper alloy. In some implementations, a diameter or width R of a cross section of the inner core 161 may be about 10 μm to about 300 μm.

The core ball 160 serves to transfer signals between the lower redistribution layer structure 110 and the substrate 180 through the first outer conductive layer 162. In some implementations, the first outer conductive layer 162 may be a SAC solder alloy including tin, silver, and copper. In some implementations, the first outer conductive layer 162 may include at least one of gold, silver, nickel, zinc, tin, aluminum, chromium, antimony, or an alloy thereof. In some implementations, a thickness T1 of the first outer conductive layer 162 may be about 1 μm to 5 μm.

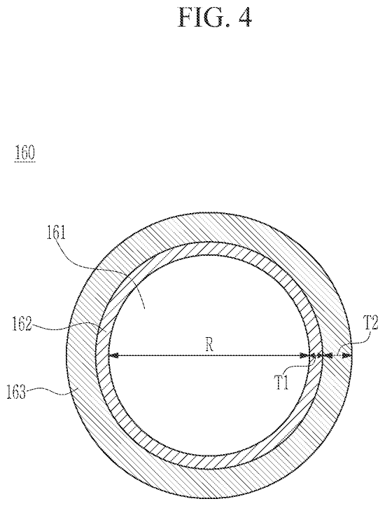

FIG. 4 illustrates a cross-sectional view showing the core ball 160.

Referring to FIG. 4, the core ball 160 may include a second outer conductive layer 163 covering the first outer conductive layer 162. A transfer speed of signals and power between the redistribution layer structure 110 at a lower portion and the substrate 180 at an upper portion may be improved by further adding the second outer conductive layer 163 to the first outer conductive layer 162 of the core ball 160. In some implementations, the second outer conductive layer 163 may be a SAC solder alloy including tin, silver, and copper. In some implementations, the second outer conductive layer 163 may include at least one of copper, gold, silver, nickel, zinc, tin, aluminum, chromium, antimony, or an alloy thereof. In some implementations, a thickness T2 of the second outer conductive layer 163 may be about 5 μm to 50 μm.

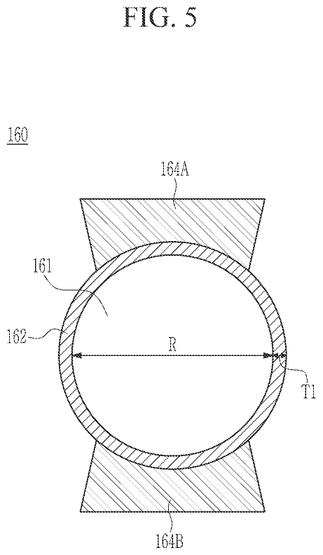

FIG. 5 illustrates a cross-sectional view showing the core ball 160.

Referring to FIG. 5, the core ball 160 may include an upper conductive connecting member 164A and a lower conductive connecting member 164B connected to the first outer conductive layer 162. The upper conductive connecting member 164A and the lower conductive connecting member 164B may each include a flat bonding surface. The flat bonding surfaces of the upper conductive connecting member 164A and the lower conductive connecting member 164B each serve to make bonding between the bonding surfaces better when the core ball 160 is bonded to other pads by a reflow process. The upper conductive connecting member 164A and the lower conductive connecting member 164B may include side surface extending from the first outer conductive layer 162 and forming an angle of 90° or less with respect to the bonding surfaces. Side surface of the upper conductive connecting member 164A and the lower conductive connecting member 164B extending from the first outer conductive layer 162 and having a constant slope are intended to maximize widths of the flat bonding surfaces of the upper conductive connecting member 164A and the lower conductive connecting member 164B, and each serve to ensure that reflow is performed within a flat bonding surface when the reflow process is performed.

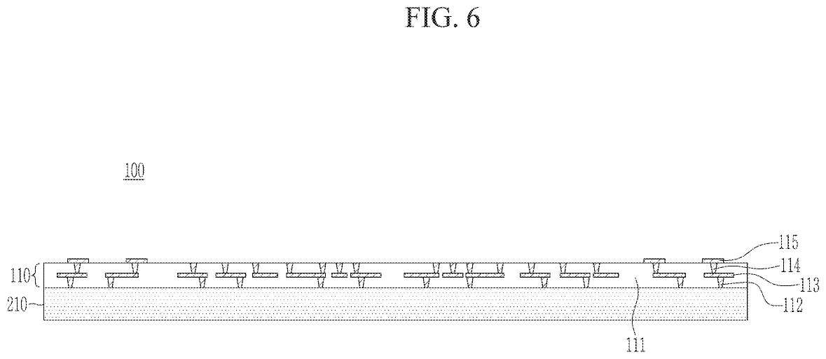

FIG. 6 to FIG. 15 illustrate cross-sectional views showing each step among steps of a method for manufacturing the semiconductor package 100.

FIG. 6 illustrates a cross-sectional view showing a step of forming the redistribution layer structure 110 on the carrier 210 as one of the steps of the method for manufacturing the semiconductor package 100.

Referring to FIG. 6, the redistribution layer structure 110 is positioned on the carrier 210. The carrier 210 may include, e.g., a silicon-based material such as glass or a silicon oxide, an organic material, or another material such as an aluminum oxide, any combination of these materials, and the like.

First, the first dielectric layer 111 is positioned on the carrier 210. In some implementations, the first dielectric layer 111 may include a photosensitive polymer layer. The photosensitive polymer is a material capable of forming fine patterns by applying a photolithography process. In some implementations, the first dielectric layer 111 may include a photosensitive dielectric (photoimageable dielectric (PID)) used in a redistribution process. In some implementations, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. In some implementations, the first dielectric layer 111 is formed of an inorganic dielectric material such as a silicon nitride, a silicon oxide, or the like. In some implementations, the first dielectric layer 111 may be formed by a CVD, ALD, or PECVD process.

After forming the first dielectric layer 111, via holes are formed by selectively etching the first dielectric layer 111, and the first redistribution layer vias 112 are formed by filling the via holes with a conductive material.

Then, the first dielectric layer 111 is additionally deposited on the first redistribution layer vias 112 and the first dielectric layer 111, the additionally deposited first dielectric layer 111 is selectively etched to form openings, and the first redistribution layer lines 113 are formed by filling the openings with a conductive material.

Then, the first dielectric layer 111 is additionally deposited on the first redistribution layer lines 113 and the first dielectric layer 111, the additionally deposited first dielectric layer 111 is selectively etched to form via holes, and the second redistribution layer vias 114 are formed by filling the via holes with a conductive material.

Then, the first dielectric layer 111 is additionally deposited on the second redistribution layer vias 114 and the first dielectric layer 111, the additionally deposited first dielectric layer 111 is selectively etched to form openings, and the connection pads 115 are formed by filling the openings with a conductive material.

In some implementations, the first redistribution layer vias 112, the first redistribution layer lines 113, the second redistribution layer vias 114, and the connection pads 115 may include at least one of copper, aluminum, tungsten, nickel, gold, tin, titanium, or an alloy thereof. In some implementations, the first redistribution layer vias 112, the first redistribution layer lines 113, the second redistribution layer vias 114, and the connection pads 115 may be formed by performing a sputtering process. In some implementations, the first redistribution layer vias 112, the first redistribution layer lines 113, the second redistribution layer vias 114, and the connection pads 115 may be formed by performing an electroplating process after forming a seed metal layer.

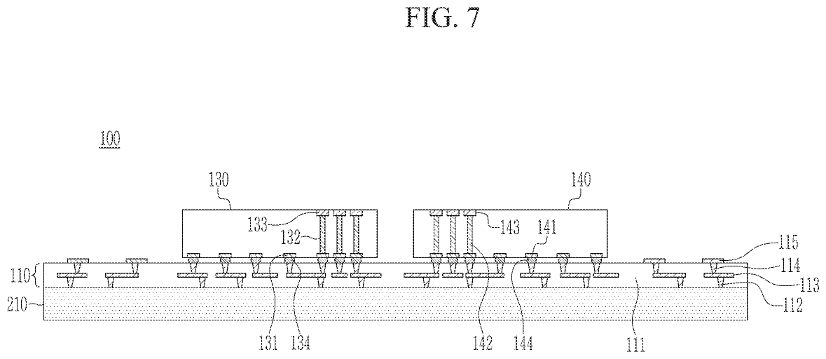

FIG. 7 illustrates a cross-sectional view showing a step of mounting the first semiconductor die 130 and the second semiconductor die 140 on the redistribution layer structure 110 as one of the steps of the method for manufacturing the semiconductor package 100.

Referring to FIG. 7, the first semiconductor die 130 and the second semiconductor die 140 are mounted on the redistribution layer structure 110 by flip chip bonding. The first semiconductor die 130 and the second semiconductor die 140 are positioned side by side and horizontally at a same level. The first connection member 134 of the first semiconductor die 130 is bonded to the second redistribution layer via 114 of the redistribution layer structure 110, so as to electrically connect the first semiconductor die 130 and the redistribution layer structure 110. The first connection member 134 of the second semiconductor die 140 is bonded to the second redistribution layer via 114 of the redistribution layer structure 110, so as to electrically connect the second semiconductor die 140 and the redistribution layer structure 110.

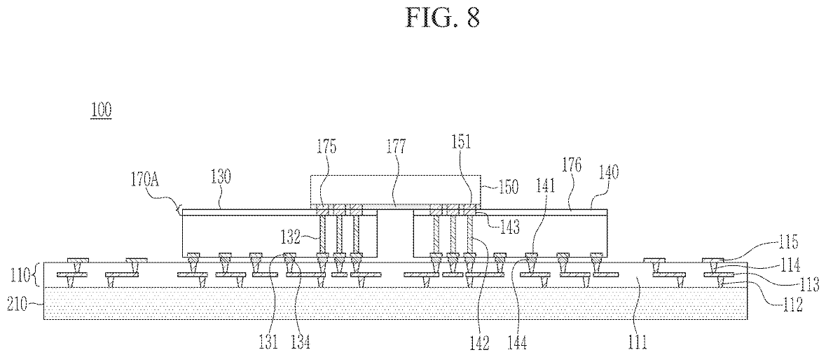

FIG. 8 illustrates a cross-sectional view showing a step of bonding the bridge die 150 onto the first semiconductor die 130 and the second semiconductor die 140 by performing hybrid bonding as one of the steps of the method for manufacturing the semiconductor package 100.

Referring to FIG. 8, the bridge die 150 is bonded to the first semiconductor die 130 and the second semiconductor die 140 by performing hybrid bonding. The bridge die 150 is positioned with an active surface facing the first semiconductor die 130 and the second semiconductor die 140. The first bonding pad 174 on the upper surface of the first semiconductor die 130 and the second semiconductor die 140 and the second bonding pad 175 on the lower surface of the bridge die 150 may be directly bonded by metal-metal hybrid bonding. A metal bond is formed at an interface between the first bonding pad 174 on the upper surface of the first semiconductor die 130 and the second semiconductor die 140 and the second bonding pad 175 on the lower surface of the bridge die 150 by metal-metal hybrid bonding. In some implementations, the first bonding pad 174 and the second bonding pad 175 may each include copper. In some implementations, the first bonding pad 174 and the second bonding pad 175 may be a metallic material to which hybrid bonding is applied.

The first bonding pad 174 on the upper surface of the first semiconductor die 130 and the second semiconductor die 140 and the second bonding pad 175 on the lower surface of the bridge die 150 are made of a same material, and after hybrid bonding, an interface may disappear between the first bonding pad 174 on the upper surface of the first semiconductor die 130 and the second semiconductor die 140 and the second bonding pad 175 on the lower surface of the bridge die 150. The first semiconductor die 130 and the bridge die 150, and the second semiconductor die 140 and the bridge die 150 may be electrically connected to each other through the first bonding pad 174 on the upper surface of the first semiconductor die 130 and the second semiconductor die 140 and the second bonding pad 175 on the lower surface of the bridge die 150.

The first insulating layer 176 on the upper surface of the first semiconductor die 130 and the second semiconductor die 140 and the second insulating layer 177 on the lower surface of the bridge die 150 may be directly bonded by non-metal-non-metal hybrid bonding. A covalent bond is formed at an interface between the first insulating layer 176 on the upper surface of the first semiconductor die 130 and the second semiconductor die 140 and the second insulating layer 177 on the lower surface of the bridge die 150 by non-metal-non-metal hybrid bonding.

In some implementations, the first insulating layer 176 and the second insulating layer 177 may include a silicon oxide or a TEOS forming oxide. In some implementations, the first insulating layer 176 and the second insulating layer 177 may each include SiO₂. In some implementations, the first insulating layer 176 and the second insulating layer 177 may each be a silicon nitride, a silicon oxynitride, or other suitable dielectric material. In some implementations, the first insulating layer 176 and the second insulating layer 177 may each include SiN or SiCN.

The first insulating layer 176 on the upper surface of the first semiconductor die 130 and the second semiconductor die 140 and the second insulating layer 177 on the lower surface of the bridge die 150 are made of a same material, and after hybrid bonding, an interface may disappear between the first insulating layer 176 on the upper surface of the first semiconductor die 130 and the second semiconductor die 140 and the second insulating layer 177 on the lower surface of the bridge die 150.

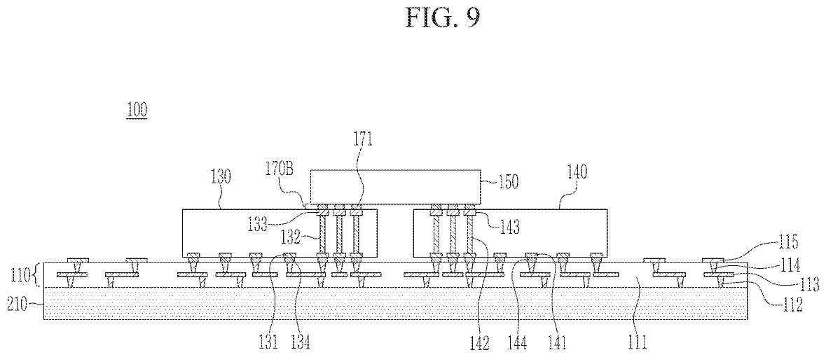

FIG. 9 illustrates a cross-sectional view showing a step of mounting the bridge die 150 on the first semiconductor die 130 and the second semiconductor die 140 using the fourth connecting member 171 as one of the steps of the method for manufacturing the semiconductor package 100. FIG. 9 illustrates a view for showing a step of flip chip bonding of the first semiconductor die 130, the second semiconductor die 140, and the bridge die 150 in the semiconductor package of FIG. 2, and for other steps of the method for manufacturing the semiconductor package of FIG. 2, the steps of the method for manufacturing the semiconductor package illustrated and described in FIG. 6 to FIG. 8 and FIG. 10 to FIG. 15 may be equally applied.

Referring to FIG. 9, the bridge die 150 is mounted on the first semiconductor die 130 and the second semiconductor die 140 using the fourth connection member 171. The bridge die 150 is positioned with an active surface facing the first semiconductor die 130 and the second semiconductor die 140. The first upper connection pad 133 of the first semiconductor die 130 and the bridge die 150 are electrically connected using the fourth connection member 171, and the second upper connection pad 143 of the second semiconductor die 140 and the bridge die 150 are electrically connected. In some implementations, the fourth connection member 171 may include a micro bump. In some implementations, the fourth connection member 171 may include at least one of tin, silver, lead, nickel, copper, or an alloy thereof.

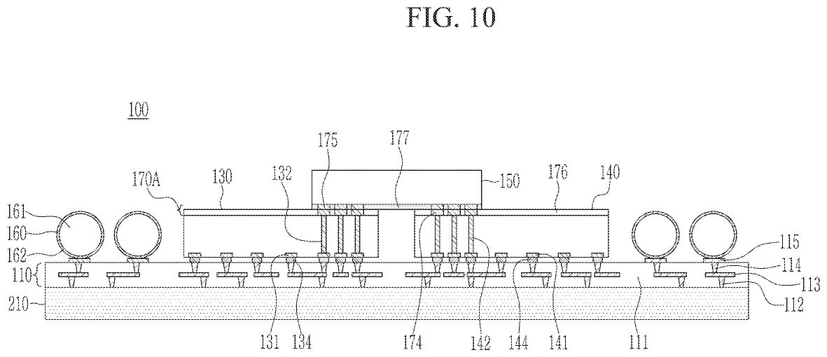

FIG. 10 illustrates a cross-sectional view showing a step of bonding the core balls 160 on the redistribution layer structure 110 as one of the steps of the method for manufacturing the semiconductor package 100.

Referring to FIG. 10, the core balls 160 are bonded to the connection pads 115 of the redistribution layer structure 110 by performing a reflow process.

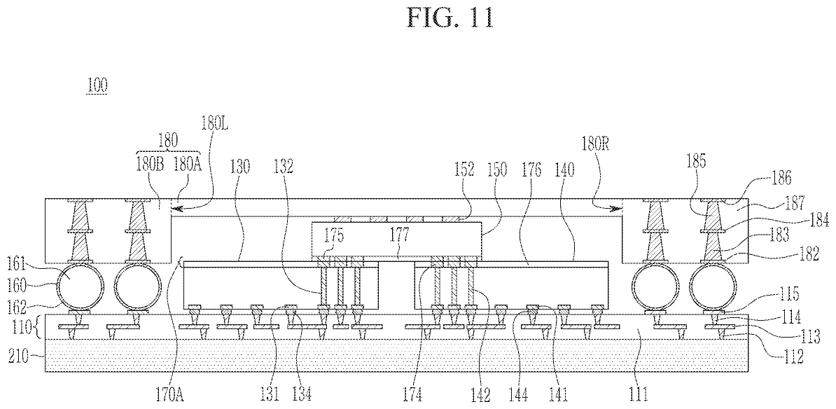

FIG. 11 illustrates a cross-sectional view showing a step of bonding the substrate 180 onto the core balls 160 as one of the steps of the method for manufacturing the semiconductor package 100.

Referring to FIG. 11, the substrate 180 is bonded to the core balls 160 by performing a thermal compression (TC) process. The solder resist patch 152 may be attached between the upper plate portion 180A of the substrate 180 and the bridge die 150.

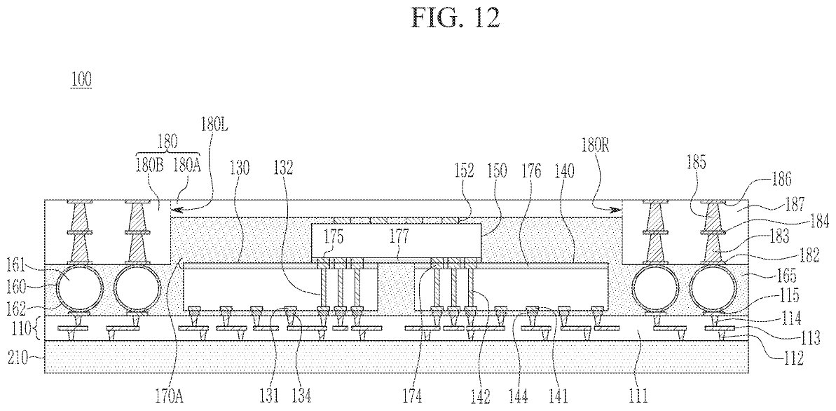

FIG. 12 illustrates a cross-sectional view showing a step of molding the first semiconductor die 130, the second semiconductor die 140, the bridge die 150, the core balls 160, and the interconnect structure 170A with the first molding material 165 on the redistribution layer structure 110 as one of the steps of the method for manufacturing the semiconductor package 100.

Referring to FIG. 12, the first semiconductor die 130, the second semiconductor die 140, the bridge die 150, the core balls 160, and the interconnection structure 170A are molded with the first molding material 165 between the redistribution layer structure 110 and the substrate 180. In some implementations, the molding process with the first molding material 165 may include a compression molding or transfer molding process. In some implementations, the first molding material 165 may be formed of a thermosetting resin such as an epoxy resin. In some implementations, the first molding material 165 may be an epoxy molding compound (EMC).

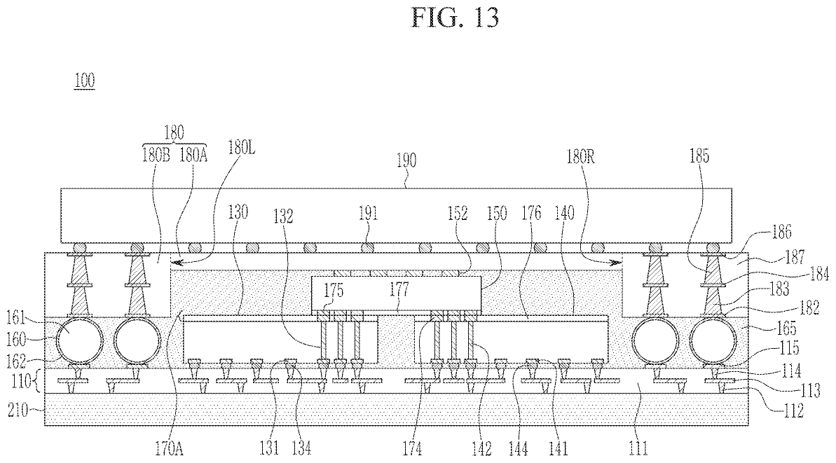

FIG. 13 illustrates a cross-sectional view showing a step of mounting the third semiconductor die 190 on the substrate 180 as one of the steps of the method for manufacturing the semiconductor package 100.

Referring to FIG. 13, the third semiconductor die 190 is mounted on the substrate 180 by flip chip bonding. The third connection member 191 of the third semiconductor die 190 is bonded to the substrate 180 so that the third semiconductor die 190 and the substrate 180 are electrically connected.

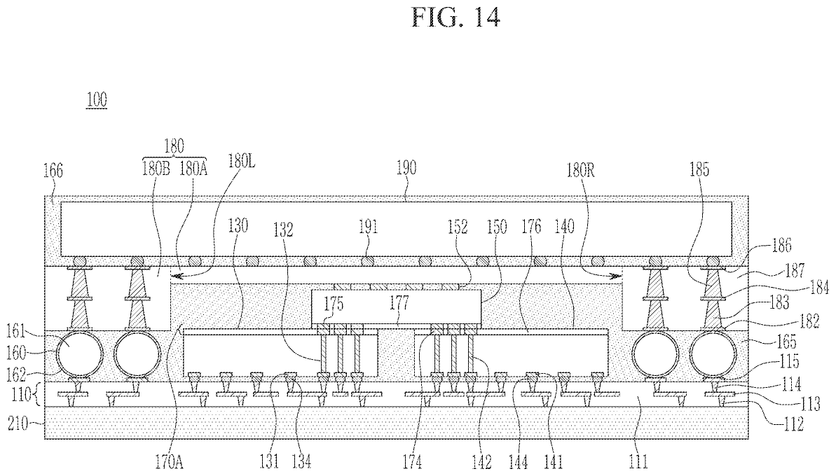

FIG. 14 illustrates a cross-sectional view showing a step of molding the third semiconductor die 190 with the second molding material 166 on the substrate 180 as one of the steps of the method for manufacturing the semiconductor package 100.

Referring to FIG. 14, the third semiconductor die 190 is molded on the substrate 180 with the second molding material 166. In some implementations, the molding process with the second molding material 166 may include a compression molding or transfer molding process. In some implementations, the second molding material 166 may be formed of a thermosetting resin such as an epoxy resin. In some implementations, the second molding material 166 may be an epoxy molding compound (EMC).

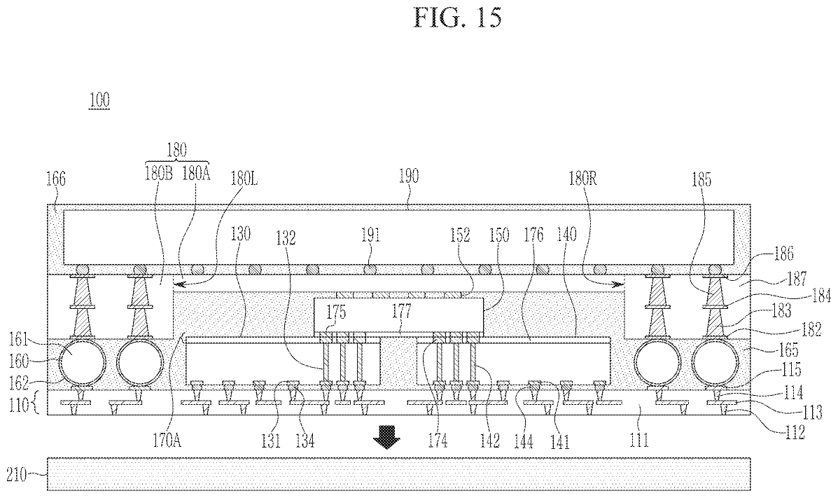

FIG. 15 illustrates a cross-sectional view showing a step of de-bonding the carrier 210 from the redistribution layer structure 110 as one of the steps of the method for manufacturing the semiconductor package 100.

Referring to FIG. 15, the carrier 210 is de-bonded from the lower surface of the redistribution layer structure 110.

Subsequently, the external connection structure 120 is positioned on the lower surface of the redistribution layer structure 110 (see FIG. 1). The insulating layer 122 may be formed under the dielectric layer 111 of the redistribution layer structure 110, and the conductive pads 121 may be formed under the first redistribution layer vias 112. In some implementations, the conductive pad 121 may include at least one of copper, nickel, zinc, gold, silver, platinum, palladium, chromium, titanium or an alloy thereof. In some implementations, the insulating layer 122 may include solder resist. In some implementations, the external connection member 123 may include at least one of tin, silver, lead, nickel, copper, or an alloy thereof. In some implementations, the conductive pad 121 may be formed by performing a sputtering process or an electrolytic plating process after forming a seed metal layer. In some implementations, the insulating layer 122 may be formed by a CVD, ALD, or PECVD process.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor package comprising:
a redistribution layer structure;
a first semiconductor die on the redistribution layer structure;
a second semiconductor die positioned on the redistribution layer structure and next to the first semiconductor die;
a plurality of core balls positioned on the redistribution layer structure and next to the first semiconductor die;
a bridge die configured to electrically connecting the first semiconductor die and the second semiconductor die to each other on the first semiconductor die and the second semiconductor die;
a substrate including an upper plate portion and a sidewall portion, wherein the upper plate portion and the sidewall portion define a cavity, wherein the upper plate portion is positioned on the bridge die, wherein the sidewall portion is positioned on the core balls, and wherein the bridge die is positioned within the cavity; and
a molding material configured to mold the first semiconductor die, the second semiconductor die, the core balls, and the bridge die between the redistribution layer structure and the substrate.

2. The semiconductor package of claim 1, wherein the first semiconductor die and the second semiconductor die are configured to exchange signals through the bridge die.

3. The semiconductor package of claim 1, wherein the first semiconductor die and the second semiconductor die each include a respective application processor (AP).

4. The semiconductor package of claim 1, wherein the bridge die includes a memory semiconductor.

5. The semiconductor package of claim 1, wherein the bridge die includes a silicon bridge die.

6. The semiconductor package of claim 1, wherein each core ball among the core balls includes an inner core and an outer conductive layer covering the inner core.

7. The semiconductor package of claim 6, wherein the inner core includes a plastic material selected from the group consisting of a thermoplastic resin, a thermosetting resin, or a polymer material.

8. The semiconductor package of claim 6, wherein the outer conductive layer includes a SAC solder alloy containing tin (Sn), silver (Ag) and copper (Cu).

9. A semiconductor package comprising:
a redistribution layer structure;
a first semiconductor die on the redistribution layer structure;
a second semiconductor die positioned on the redistribution layer structure and next to the first semiconductor die;
a plurality of core balls positioned on the redistribution layer structure and next to the first semiconductor die;
an interconnection structure on the first semiconductor die and the second semiconductor die;
a bridge die on the interconnection structure, wherein the interconnection structure electrically connects the bridge die to the first semiconductor die, and the bridge die and the second semiconductor die, and wherein the bridge die electrically connects the first semiconductor die and the second semiconductor die;
a substrate including an upper plate portion and a sidewall portion, wherein the upper plate portion and the sidewall portion define a cavity, wherein the upper plate portion is positioned on the bridge die, wherein the sidewall portion is positioned on the core balls, and wherein the bridge die is positioned within the cavity;
a molding material configured to mold the first semiconductor die, the second semiconductor die, the core balls, and the bridge die between the redistribution layer structure and the substrate; and
a third semiconductor die on the substrate.

10. The semiconductor package of claim 9, wherein the interconnection structure includes a plurality of connection members, and at least one connection member of the plurality of connection members includes a micro bump.

11. The semiconductor package of claim 10, wherein the plurality of connection members are molded by the molding material.

12. The semiconductor package of claim 9, wherein the interconnection structure includes:
a plurality of first bonding pads and a first insulating layer on upper surfaces of the first semiconductor die and the second semiconductor die; and
a plurality of second bonding pads and a second insulating layer on a lower surface of the bridge die.

13. The semiconductor package of claim 12, wherein each first bonding pad of the first bonding pads is directly bonded to each second bonding pad of the second bonding pads.

14. The semiconductor package of claim 12, wherein the first insulating layer is directly bonded to the second insulating layer.

15. The semiconductor package of claim 9, wherein the third semiconductor die includes a memory semiconductor.

16. The semiconductor package of claim 9, wherein the first semiconductor die and the second semiconductor die each comprise a plurality of through silicon vias (TSVs), and
wherein the through silicon vias electrically connect the bridge die connected to the interconnection structure to the redistribution layer structure.

17. A manufacturing method for a semiconductor package, comprising:
forming a redistribution layer structure on a carrier;
mounting a first semiconductor die and a second semiconductor die next to each other on the redistribution layer structure;
bonding a bridge die on the first semiconductor die and the second semiconductor die;
bonding a plurality of core balls on the redistribution layer structure;
bonding a substrate on the core balls, wherein the substrate includes an upper plate portion and a sidewall portion, wherein the upper plate portion and the sidewall portion define a cavity, wherein the upper plate portion is positioned on the bridge die, wherein the sidewall portion is positioned on the core balls, and wherein the bridge die is positioned within the cavity; and
molding the first semiconductor die, the second semiconductor die, the core balls, and the bridge die with a molding material between the redistribution layer structure and the substrate.

18. The manufacturing method of claim 17, wherein bonding the substrate on the core balls is performed by a thermal compression bonding process.

19. The manufacturing method of claim 17, wherein bonding the core balls on the redistribution layer structure is performed by a reflow process.

20. The manufacturing method of claim 17, wherein bonding the bridge die on the first semiconductor die and the second semiconductor die is performed by hybrid bonding.
